(19) United States
(12) Patent Application Publication
(10) Pub. No.: US 2026/0149556 A1
(43) Pub. Date: May 28, 2026

(54) METASTABILITY DETECTOR AND CALIBRATION METHOD FOR SYNCHRONOUS DATA TRANSFER

(71) Applicant: Stichting IMEC Nederland, Eindhoven (NL)

(72) Inventors: Sahan Gamage, Cambridge (GB); Stefano Traferro, Eindhoven (NL); Evgenii Tiurin, Geldrop (NL)

(21) Appl. No.: 19/394,335

(22) Filed: Nov. 19, 2025

(30) Foreign Application Priority Data
Nov. 25, 2024 (EP) 24215097.7

(51) Int. Cl. H04L 7/033; H03K 19/21; H03L 7/06

(52) U.S. Cl. CPC H04L 7/033; H03K 19/21; H03L 7/06

(57) ABSTRACT

The present disclosure provides a metastability detector and a calibration method for synchronous data transfer in distributed synchronous systems. The metastability detector integrates hardware adapted to, for reference signal patterns sent from first transceiver device to a second transceiver device, determine a metastability value based on deviations from the 50% duty cycle. The calibration method adjusts clock phases of generated signal patterns based on metastability values determined by measuring deviations from the 50% duty cycle. The example embodiments of the present disclosure provide reliable, high-speed data transfer with minimal synchronization issues in distributed synchronous systems. The metastability detector and calibration method may further account for variations over time and may maintain optimal performance of data transfer in distributed synchronous systems.

### CROSS-REFERENCE TO RELATED APPLICATIONS

The present application is a non-provisional patent application claiming priority to European Patent Application No. 24215097.7, filed November 25, 2024, the contents of which are hereby incorporated by reference.

### FIELD OF THE DISCLOSURE

The present disclosure relates to the field of high-speed data communication in distributed digital hardware systems, and more specifically to methods and devices for reliable synchronous data transfer.

### BACKGROUND

High-speed data transfer between distributed digital hardware systems may impact the performance of various modern technologies, such as ultra-wideband (UWB) transceivers, radar systems, or localization networks. These systems often rely on synchronous communication, where the transmitter (TX) and receiver (RX) operate on aligned frequencies for accurate data exchange. However, achieving reliable phase synchronization between distributed components presents significant challenges.

One concern in high-speed synchronous data transmission is the distortion or degradation of reference clock signals transmitted between the RX and TX systems. The frequency at which the clock signals start to degrade or start being distorted may depend on multiple factors, such as the process node/technology used to manufacture the circuit or packaging, and may also depend on operational conditions, such as temperature of operation and/or supply voltage.

Even with the use of techniques, such as Low Voltage Differential Signaling (LVDS), clock signals may become distorted or degraded due to factors, such as signal attenuation and electromagnetic interference. This degradation may make it difficult for the TX system to accurately reproduce the RX clock for its digital operations.

Additionally, the physical signal path between the TX and RX may introduce further complications. Signals go through a series of components, such as connectors and bonding wires, each contributing to potential signal delay and distortion. This may alter the clock phase by the time the signal reaches the RX digital sampling point, leading to inconsistencies in data timing.

In applications using precise timing synchronization, these timing uncertainties may have negative effects. Variations in delay may introduce unacceptable levels of jitter, undermining the accuracy and reliability of the distributed system.

Despite some methods having attempted to address these issues, such as improving connection quality or reducing operational frequencies, challenges may remain in providing reliable high-speed data transfer without compromising performance in distributed synchronous systems. Environmental factors like temperature fluctuations and variations in connector wiring may further increase the chance of metastability occurring.

### SUMMARY

The present disclosure provides a metastability detector for detecting metastability of a received signal in a distributed synchronous system.

The present disclosure provides a method for calibrating a distributed synchronous system.

The example embodiments of the present disclosure provide a distributed synchronous system comprising at least a metastability detector.

The example embodiments of the present disclosure provide a method for high-speed data transfer in a distributed synchronous system using a metastability detector.

In a first example embodiment, which may be combined with other example embodiments described herein, the present disclosure relates to a metastability detector for detecting metastability of a received signal in a distributed synchronous system. The metastability originating from clock phase misalignment resulting from sending the signal from a first transceiver device, e.g., a transmitter device, to a second transceiver device, e.g., a receiver device, of the distributed synchronous system. The metastability detector includes an input configured to receive a re-synchronized signal pattern from a synchronizer device of the second transceiver device, e.g., receiver device. The re-synchronized signal pattern is obtained by re-synchronization to a signal pattern (e.g., present) in the received signal and resulting from a toggle sequence generated in the first transceiver device, e.g., the transmitter device, with a first clock phase and a 50% duty cycle. The metastability detector further includes an interval counter configured to increment when the re-synchronized signal pattern is equal to 1 and to decrement when the re-synchronized signal pattern is equal to 0, or vice versa for subsequent logic level intervals of the re-synchronized signal pattern. The metastability detector further includes control logic (e.g., a controller) configured to accumulate an absolute value of the interval counter at the end of each logic level interval and to provide a metastability value based on the accumulated absolute value.

A metastability detector according to example embodiments of the present disclosure may be used in any highspeed data system such as, for example but not limited to, Ultra Wide Band (UWB) systems, localization detector setup systems, radar systems, monitoring systems etc., where synchronous clocks are used. A metastability detector according to example embodiments of the present disclosure does not use a pre-defined pattern, but (e.g., only) uses the first transceiver device logic 0 and logic 1 durations to be the same. Since it reports metastability at logic edges, e.g. logic 0 to logic 1 transition, keeping the input at, for example, logic 0 at the beginning or end of the toggle sequence is adequate as pattern termination.

According to example embodiments of the present disclosure, the metastability detector may further comprise an internal register for saving the metastability value. The internal register may be accessible to external software.

The control logic (e.g., controller, which may include a memory storing computer-executable instructions, such as an internal register, and at least one processor configured to access the memory and execute the instructions) may further be configured to compare the accumulated counts to a predetermined threshold to determine if a metastability event has occurred. In that way, metastability may be determined in a predetermined (e.g., accurate) manner.

In a second example embodiment, which may be combined with example embodiments described herein, the present disclosure relates to a method for calibrating a distributed synchronous system including a first transceiver device with a first transceiver digital sub-system connected to a second transceiver device with a second transceiver digital sub-system via an external connection. The method includes a plurality of steps. The plurality of steps may include a step (a), wherein step (a) includes generating a toggle sequence with a clock phase and a 50% duty cycle in a pattern generator in the first transceiver digital sub-system, and transmitting a signal containing the toggle sequence to the second transceiver. The plurality of steps may further include a step (b), wherein step (b) includes receiving the signal in the second transceiver, and synchronizing to a signal pattern present in the received signal and resulting from the toggle sequence with a synchronizer device in the second transceiver digital sub-system, thereby obtaining a re-synchronized signal pattern. The plurality of steps may further include a step (c), wherein step (c) includes incrementing an interval counter when the re-synchronized signal pattern is equal to 1 and decrementing the interval counter when the re-synchronized signal pattern is equal to 0 or vice versa for subsequent logic level intervals of the re-synchronized signal. The plurality of steps may further include a step (d), wherein step (d) includes accumulating an absolute value of the interval counter at the end of each logic level interval and providing a metastability value based on the accumulated absolute value. The plurality of steps may further include a step (e), wherein step (e) includes optionally repeating steps (a) to (d) at least once for a further toggle sequence with a different clock phase and with a 50% duty cycle, thereby obtaining at least one further metastability value. The plurality of steps may further include a step (f), wherein step (f) includes evaluating whether the obtained metastability value or values reflect a minimal or zero metastability. The plurality of steps may further include a step (g), wherein step (g) includes determining a reference clock phase correlated with the respective metastability value reflecting the minimal or zero metastability. The plurality of steps may further include a step (h), wherein step (h) includes adjusting the clock phase of a signal for data transfer from the first transceiver device to the second transceiver device or vice versa based on the reference clock phase.

The evaluation step may, according to example embodiments of the present disclosure, comprise comparing the obtained metastability value or values with a predetermined value. In that way, the metastability values may be determined in a predetermined (e.g., accurate way).

According to example embodiments, steps (a) to (d) may be repeated for subsequent toggle sequences of which the clock phase is adjusted in discrete steps over a range of clock phases.

To be sure that metastability is as low as possible, according to example embodiments of the present disclosure, the method may further comprise periodically re-run steps (a) to (h) in between data transfer operations.

In a third example embodiment, which may be combined with other example embodiments described herein, the present disclosure relates to a distributed synchronous system comprising a first transceiver device with a first transceiver digital sub-system connected to a second transceiver device with a second transceiver digital sub-system via an external connection. The first transceiver digital sub-system comprises a pattern generator for generating a toggle sequence with a clock phase and a 50% duty cycle and is configured to generate subsequent toggle sequences with different clock phases. The second transceiver digital sub-system comprises a synchronizer device, which may, for example, comprise at least two Flip-Flop synchronizers, configured to receive a signal pattern present in a received signal and resulting from a toggle sequence generated in the first transceiver device, and to produce a re-synchronized signal pattern by re-synchronization to the received signal pattern. The second transceiver digital sub-system may further comprise a metastability detector device to provide a metastability value of the re-synchronized signal pattern indicative of the degree of metastability of the re-synchronized signal pattern. The metastability detector device comprises at least one metastability detector according to example embodiments of the present disclosure, and/or the distributed synchronous system is configured to perform, before use or in between data transfer operations, a calibration method according to example embodiments of the present disclosure for obtaining synchronized data transfer between the first transceiver device and the second transceiver device.

A distributed synchronous system according to example embodiments of the present disclosure provides that reliable high-speed data transfer between a first transceiver device and a second transceiver device may be achieved even when clock phase synchronicity cannot be guaranteed due to environmental and/or operational factors. Metastability events in signals received in the second transceiver device may be reduced or eliminated, thereby increasing data transfer reliability.

According to example embodiments of the present disclosure, the metastability detector system may further comprise at least one XOR based metastability detector and/or at least one pattern based metastability detector.

The system may be configured to periodically re-run the calibration method in between data transfer operations.

According to example embodiments of the present disclosure, the first transceiver device may, for example, comprise a field-programmable gate array with a phase-locked loop for clock phase adjustment.

According to example embodiments of the present disclosure, the second transceiver device may, for example, comprise an integrated circuit configured to provide a reference clock phase to the first transceiver device.

The external connection may comprise a transmitter core, transmitter pads, wires, receiver pads, and a receiver core.

In a fourth example embodiment, which may be combined with example embodiments described herein, the present disclosure relates to a method for transferring (e.g., enabling) reliable high-speed data transfer in a distributed synchronous system comprising a first transceiver device with a first transceiver digital sub-system connected to a second transceiver device with a second transceiver digital sub-system via an external connection. The method comprises a first step of implementing, at the second transceiver digital sub-system, a metastability detector device configured to detect metastability events resulting from clock phase misalignment. The metastability detector system comprises at least one metastability detector according to example embodiments of the present disclosure. In a second step, the method comprises providing at the first transceiver device, a pattern generator for generating a toggle sequence with a particular clock phase and a 50% duty cycle, and configured to adjust the clock phase over a range of phases and to generate subsequent toggle sequences corresponding to each adjusted clock phase, and/or performing, before use and/or in between data transfer operations, a calibration method according to example embodiments of the present disclosure. Then, the method comprises selecting a clock phase resulting in a minimal or zero metastability for data transfer and transferring data from the transmitter device to the receiver device using the selected clock phase.

### BRIEF DESCRIPTION OF THE FIGURES

The above, as well as additional, features will be better understood through the following illustrative and non-limiting detailed description of example embodiments, with reference to the appended drawings.

FIG. 1 schematically illustrates a distributed synchronous system according to example embodiments of the present disclosure.

FIG. 2 schematically illustrates a diagram of an example of a metastability detector according to example embodiments of the present disclosure.

FIG. 3 is a timing diagram of possible metastable edges and the result of a metastability detector according to example embodiments of the present disclosure.

All the figures are schematic, not necessarily to scale, and generally show parts which are necessary to elucidate example embodiments, wherein other parts may be omitted or merely suggested.

### DETAILED DESCRIPTION

Example embodiments will now be described more fully hereinafter with reference to the accompanying drawings. That which is encompassed by the claims may, however, be embodied in many different forms and should not be construed as limited to the embodiments set forth herein; rather, these embodiments are provided by way of example. Furthermore, like numbers refer to the same or similar elements or components throughout.

Below, example embodiments according to the disclosure are described with reference to certain drawings, but the disclosure is not limited thereto. The drawings described are schematic and are non-limiting. In the drawings, the size of some of the elements may be exaggerated and not drawn to scale for illustrative purposes. The dimensions and the relative dimensions may not necessarily correspond to actual reductions to practice of the disclosure.

The terms first, second, third, and the like in the description and in the claims, are used for distinguishing between similar elements and not necessarily for describing a sequential or chronological order. The terms may be interchangeable in some circumstances, and the example embodiments of the disclosure may operate in other sequences than described or illustrated herein.

The terms top, bottom, over, under, and the like in the description and the claims are used for descriptive purposes and not necessarily for describing relative positions. The terms so used are interchangeable under appropriate circumstances, and the example embodiments of the disclosure described herein may operate in other orientations than described or illustrated herein.

The present disclosure will hereinafter be described with different example embodiments. These example embodiments are for the ease of understanding the present disclosure and are not intended to limit the disclosure in any way.

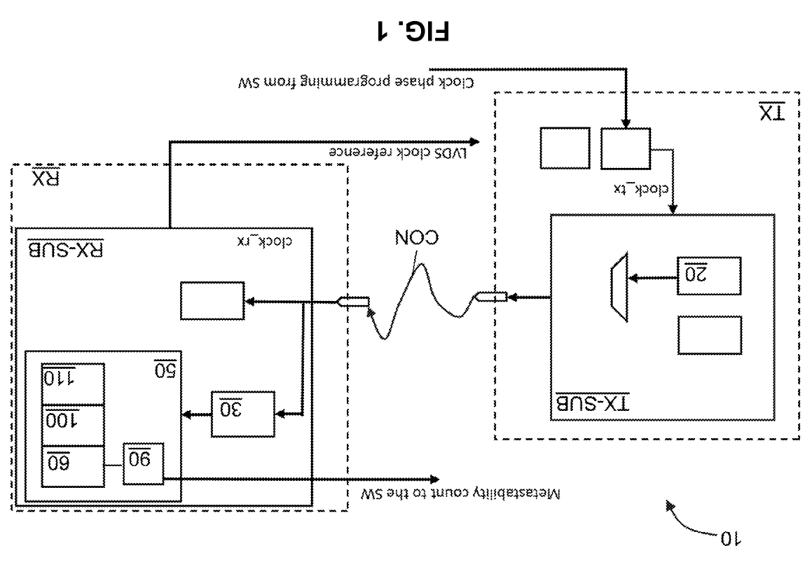

FIG. 1 schematically illustrates a distributed synchronous system 10 according to example embodiments of the present disclosure. A “distributed synchronous system”, as used herein and unless otherwise specified, refers to a network of interconnected devices or components that operate with synchronized clock signals, thereby allowing data exchange across different devices within the system. Examples of such distributed synchronous systems may be, but are not limited to, a highspeed data system, such as Ultra-Wide Band (UWB) systems, localization detector setup systems, radar systems, monitoring systems, multi-module computing systems, synchronized communication networks, clock-synchronized industrial control systems and/or the like, where synchronous clocks are used.

The distributed synchronous system 10 comprises a first transceiver device, e.g., transmitter device TX, and a second transceiver device, e.g., receiver device RX.

The term “first transceiver device” refers to a transmitting component in the distributed synchronous system that both sends and receives signals and is (e.g., primarily) responsible for generating and transmitting a toggle sequence to the second transceiver device. Examples may comprise a transmitter device, such as a field-programmable gate array (FPGA) configured for signal transmission.

The term “second transceiver device” refers to a receiving component in the distributed synchronous system that both sends and receives signals and is (e.g., primarily) responsible for receiving signals from the first transceiver device and processing them through synchronization and metastability detection mechanisms. Examples may include a receiver device, such as an integrated circuit (IC) configured to handle incoming data signals.

According to example embodiments of the present disclosure, the first transceiver device may, for example, be a field-programmable gate array (FPGA) with a phase-locked loop (PLL) for flexible clock phase adjustment, and the second transceiver device may, for example, be an integrated circuit providing a reference clock phase to the first transceiver device, providing (e.g., ensuring) stable synchronization.

The present disclosure will be further described with a transmitter device TX as a first transceiver device and a receiver device RX as a second transceiver device, but this is not intended to limit the present disclosure. The transmitter device TX may be connected to the receiver device RX via an external connection CON, which may comprise a transmitter core, transmitter pads, wires, receiver pads, and a receiver core.

The transmitter device TX comprises a transmitter digital sub-system TX-SUB which comprises a pattern generator 20 capable of generating toggle sequences with a first clock phase and a 50% duty cycle. The “50% duty cycle” refers to a signal characteristic where the signal is in the high state (‘1’) for half of the period and in the low state (‘0’) for the other half, resulting in equal durations of logic ‘1’ and logic ‘0’ states within each cycle. The pattern generator 20 may be configured to generate subsequent toggle sequences, and each toggle sequence may have a different clock phase, which may be part of a range of clock phases. The clock phase of the generated patterns may be adjusted and programmed by external software.

As used herein and unless otherwise specified, the term “toggle sequence” refers to a predetermined pattern of alternating logical states (e.g., logic1 and logic0) generated by the transmitter device TX with a specific clock phase and duty cycle, such as a 50% duty cycle, and used herein to calibrate the synchronization between the transmitter device TX and the receiver device RX.

When a signal is transmitted from the transmitter device TX to the receiver device RX in a distributed synchronous system, metastability may arise due to clock phase misalignment. “Metastability” is a condition in digital circuits where a signal fails to settle into a stable logical state within an expected time frame, often due to asynchronous inputs or timing violations, leading to unpredictable behaviour. Metastability may refer to a situation where the system’s behaviour becomes unpredictable and unstable due to asynchronous interaction between the transmitter device TX and the receiver device RX. “Clock phase misalignment” may refer to the discrepancy in timing between the clock signals of the transmitter device TX and the receiver device RX.

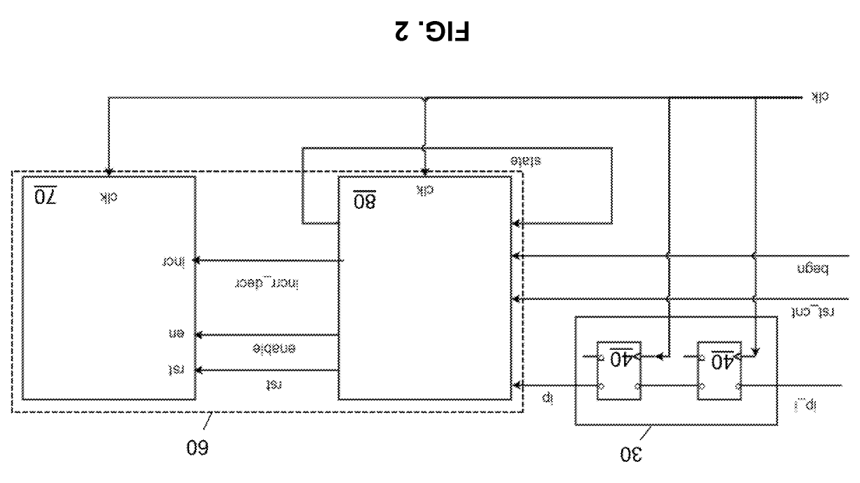

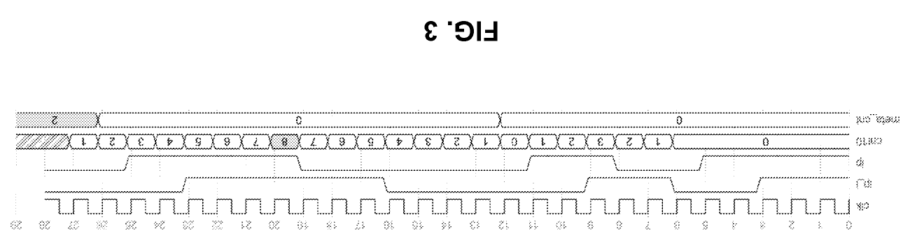

Therefore, the receiver device RX comprises, in a receiver digital sub-system RX-SUB, a synchronizer device 30 adapted for receiving a signal comprising the generated signal pattern (ip_i in FIGS. 2 and 3), resulting from the toggle sequence generated in the transmitter device TX. From this received signal ip_i, the synchronizer device 30 produces a re-synchronized signal pattern (ip in FIGS. 2 and 3) by re-synchronization of the received signal pattern. The re-synchronized signal pattern ip is thus the signal obtained after the signal that was received from the transmitter device TX has been processed by the synchronizer device 30, thereby aligning that received signal ip_i with the clock of the receiver device RX.

The synchronizer device 30 may comprise two or three back-to-back digital Flip Flop synchronizers 40 (see FIG. 2). Having multiple Flip Flop synchronizers 40 may reduce the probability of metastability in the re-synchronized signal. Using two or three Flip Flop synchronizers 40 will facilitate reducing metastability in the re-synchronized signal. However, the back-to-back digital Flip Flop synchronizers 40 may incur different clock delays, due to preceding Flip Flop synchronizers in the chain, missing the voltage transition when metastability happens. This may introduce an unpredictable delay in the captured output versus input of the synchronizer device 30.

Therefore, the receiver digital sub-system RX-SUB further comprises a metastability detector device 50 to provide a metastability value of the re-synchronized signal pattern indicative of the degree of metastability of the re-synchronized signal pattern. The metastability detector device 50 may comprise at least one metastability detector 60 according to example embodiments of the present disclosure. The metastability detector 60 comprises an input configured to receive the re-synchronized signal pattern from the synchronizer device 30. This re-synchronized signal pattern is obtained by re-synchronizing to a signal pattern present in the received signal, which results from a toggle sequence generated in the transmitter device TX with a specific clock phase and a 50% duty cycle.

As illustrated in FIG. 2, the metastability detector 60 comprises an interval counter 70 and control logic 80. The interval counter 70 is configured to increment when the re-synchronized signal pattern equals 1 and to decrement when it equals 0, or vice versa (e.g., to increment when the re-synchronized signal pattern equals 0 and to decrement when it equals 1), for subsequent logic level intervals of the re-synchronized signal pattern (signal incrr_decr in FIG. 2). The control logic 80 is configured to accumulate an absolute value of the interval counter 70 at the end of each logic level interval and to provide a metastability value based on the accumulated absolute value.

According to example embodiments of the present disclosure, the control logic 80 may further be configured to compare the accumulated counts to a predetermined threshold to determine if a metastability event has occurred, providing a (e.g., clear) indication of problematic metastability.

Additionally, the metastability detector 60 may comprise an internal register 90 for storing (e.g., saving) the metastability value. The internal register 90 may be accessible to external software, facilitating (e.g., easy) monitoring and analysis of metastability events. Further, clock phase programming of the signal pattern in the pattern generator 20 may then be done using the metastability values stored in the internal register 90.

A metastability detector 60 according to example embodiments of the present disclosure may also be referred to as an interval-based detector.

According to example embodiments of the present disclosure, the metastability detector device 50 may further comprise, next to the at least one metastability detector 60, at least one pattern-based detector 100. A pattern-based detector 100 is based on a deterministic calibration pattern sent by the transmitter device TX. Logic1 and Logic0 level durations for the used pattern may be pre-programmed in the pattern-based detector 100. When active, the pattern-based detector 100 tries to synchronize itself with a pattern using first Logic 0 to Logic 1 transition at the input. The transmitter device TX starts reference pattern generation based on pre-programmed pattern parameters. The receiver device RX counts the mismatches of reference-vs-incoming pattern. This then forms the metastability counter of the pattern-based detector 100. The pattern-based detector 100 may be an additional pattern-based detector 100 to be used next to an interval-based detector 60 according to example embodiments of the present disclosure. Using such pattern-based detector 100 in combination with an interval-based metastability detector 60, according to example embodiments of the present disclosure, may alter the working of a metastability detector device 50 compared to when (e.g., only) a pattern-based detector 100 would be used. A challenge of pattern-based detector 100 may be that the pattern generated by it has to be pre-agreed between the transmitter device TX and the receiver device RX. Hence, the possible various patterns may be anticipated at the time of implementation.

In further example embodiments of the present disclosure, the metastability detector device 50 may further comprise at least one XOR-based detector 110. A XOR-based detector 110 works based on a metastability detection scheme that captures a metastability condition, i.e., slow transition between the first and second re-synchronizer Flip Flop synchronizer, by sampling the signal after the first.

Flip Flop synchronizer flows at different times and then compares the resulting logic levels. Mismatch events are then counted at a metastability counter of the XOR-based detector 110. A XOR-based detector 110 may, similar to the pattern-based detector 100, be used next to an interval-based detector 60 according to example embodiments of the present disclosure. Using the XOR-based detector 110 in combination with an interval-based metastability detector 60, according to example embodiments of the present disclosure, may alter the working of a metastability detector device 50 compared to using only a XOR-based detector 110. A XOR-based detector 110 may, for some applications, have a propagation delay, which provides that there is a time lag between when the metastability occurs and when it is detected. This delay may be impactful (e.g., significant) in high-speed systems.

According to example embodiments and as illustrated in FIG. 1, a distributed synchronous system 10 may comprise at least one metastability detector 50 in combination with at least one pattern-based detector 100 and at least one XOR-based detector 110.

The distributed synchronous system 10 may further be configured to perform, before use or in between data transfer operations, a calibration method according to example embodiments of the present disclosure for obtaining synchronized data transfer between the transmitter device TX and the receiver device RX.

Hence, in a further example embodiment, the present disclosure provides a method for calibrating a distributed synchronous system 10. The system 10 includes a first transceiver device (e.g., a transmitter device TX) with a first transceiver digital sub-system (e.g., a transmitter digital sub-system TX-SUB) connected to a second transceiver device (e.g., receiver device RX) with a second transceiver digital sub-system (e.g. a receiver digital sub-system RX-SUB) via an external connection CON. Similar to the description of the distributed synchronous system 10, a transmitter device TX and a receiver device RX will be used to describe the calibration method according to example embodiments of the present disclosure. This is not intended to limit the present disclosure in any way.

The method comprises a plurality of steps. The plurality of steps may include a step (a), wherein step (a) includes generating a toggle sequence with a particular clock phase and a 50% duty cycle in a pattern generator 20in the transmitter digital sub-system TX-SUB, and transmitting a signal ip_i containing the toggle sequence to the receiver device RX.

The plurality of steps may further include a step (b), wherein step (b) includes receiving the signal ip_i in the receiver device RX, and synchronizing to a signal pattern present in the received signal ip_i and resulting from the toggle sequence with a synchronizer device 30 in the receiver digital sub-system RX-SUB, thereby obtaining a re-synchronized signal pattern ip.

The plurality of steps may further include a step (c), wherein step (c) includes incrementing an interval counter 70 when the re-synchronized signal pattern is equal to 1 and decrementing the interval counter 70 when the re-synchronized signal pattern is equal to 0 or incrementing an interval counter 70 when the re-synchronized signal pattern is equal to 0 and decrementing the interval counter 70 when the re-synchronized signal pattern is equal to 1 (signal incrr_decr in FIG. 2) for subsequent logic level intervals of the re-synchronized signal ip.

The plurality of steps may further include a step (d), wherein step (d) includes accumulating an absolute value of the interval counter 70 at the end of each logic level interval and providing a metastability value based on the accumulated absolute value.

The plurality of steps may further include a step (e), wherein step (e) includes optionally repeating steps a to d at least once for a further toggle sequence with a different clock phase and with a 50% duty cycle, thereby obtaining at least one further metastability value.

The plurality of steps may further include a step (f), wherein step (f) includes evaluating whether the obtained metastability value or values reflect a minimal or zero metastability.

The plurality of steps may further include a step (g), wherein step (g) includes determining a reference clock phase correlated with the respective metastability value reflecting the minimal or zero metastability.

The plurality of steps may further include a step (h), wherein step (h) includes adjusting the clock phase of a signal for data transfer from the first transceiver device to the second transceiver device or vice versa according to the reference clock phase.

According to example embodiments of the present disclosure, steps (a) to (d) may be repeated for subsequent toggle sequences of which the clock phase is adjusted in discrete steps over a range of clock phases.

According to example embodiments of the present disclosure, the calibration method may comprise generating toggle sequences at varying clock phases stepped over a full 360-degree range from the transmitter device TX to the receiver device RX. Metastability values may be measured at the receiver device RX for each clock phase. The method may identify the clock phase corresponding to the highest measured metastability value and then select a clock phase for subsequent data transfer that is approximately 180 degrees offset from this phase to minimize metastability during operation. By selecting a clock phase offset by approximately 180 degrees from the clock phase at which maximum metastability is observed, the system may operate, and thus data transfer between the transmitter device TX and receiver device RX may occur, at the phase with minimal metastability risk.

Evaluating the metastability values may comprise comparing these values with a predetermined threshold to ascertain if metastability is within acceptable limits. Repeating the toggle sequence generation and metastability determination steps over a range of clock phases may facilitate (e.g., enable) finding the optimal clock phase that minimizes metastability. Periodically re-running the calibration steps between data transfer operations may then account for (e.g., any) changes in operating conditions over time and may be done so that data transfer between the transmitter device TX and the receiver device RX is accomplished with (e.g., at least) a reduced amount of metastability in the signal received in the receiver device RX. In example cases, data transfer may occur without any form of metastability in a signal after being sent from the transmitter device TX to the receiver device RX.

The distributed synchronous system 10 may further be provided (e.g., designed) to periodically re-run the calibration sequence in between data transfer operations, providing improved (e.g., optimal) synchronization over time. Hence, “normal” data transfer operations may be, at certain times, alternated with calibration sequences. This may provide data transfer with substantially no metastability after the signal is sent from the transmitter device TX to the receiver device RX, or at least with a reduced metastability.

In still a further example embodiment, the present disclosure provides a method for facilitating (e.g., enabling) reliable high-speed data transfer in a distributed synchronous system 10 comprising a first transceiver device (e.g., transmitter device TX) with a first transceiver digital sub-system (e.g., a transmitter digital sub-system TX-SUB) connected to a second transceiver device (e.g., receiver device RX) with a second transceiver digital sub-system (e.g., receiver digital sub-system RX-SUB) via an external connection CON. The method comprises, in a first step, implementing, at the second transceiver digital sub-system, a metastability detector device 50 configured to detect metastability events resulting from clock phase misalignment. The metastability detector device 50 comprises at least one metastability detector. In a second step, the method includes providing at the first transceiver device TX, a pattern generator 20 for generating a toggle sequence with a particular clock phase and a 50% duty cycle and is configured to generate toggle sequences with different clock phases, and/or performing a calibration method before use and/or in between data transfer operations, according to example embodiments of the present disclosure. The method then further comprises selecting a clock phase resulting in a minimal or zero metastability for data transfer and transferring data from the transmitter device (TX) to the receiver device (RX) using the selected clock phase.

According to example embodiments of the present disclosure, the metastability detector device 50 may further comprise at least one pattern-based detector 100 and/or at least one XOR based detector 110, next to the at least one interval-based metastability detector 60.

FIG. 3 shows a diagram illustrating possible metastable edges and the operation of the interval-based metastability detector 60 according to example embodiments of the present disclosure. In the example of FIG. 3, the toggle sequence ip_i generated by pattern generator 20 in the transmitter digital sub-system TX-SUB is sent to the receiver device RX as part of the calibration process according to example embodiments of the present disclosure. In the example, it is provided that the edge at clock 16 of ip_i has become metastable. Because of that, the synchronizer device output (ip) will be one cycle delayed to clock number 19. The other edges remain the same as they would be without metastability. This provides that (e.g., only) at clock number 19 ip has a different delay compared to ip_i, (e.g., all) the other edges in ip are 2 clocks delayed with respect to ip_i, whereas ip_i at clock 16 is delayed by three clocks due to metastability (e.g., only) affecting that edge. Because, relatively, this makes logic 1 one cycle longer and logic 0 one less cycle, it will count 2 as the metastability counter value. The meta_cnt is then saved in the internal register 90 and may be read back by external software that runs the calibration method (e.g., routine).

In practice, the interval counter 70 checks the durations of Logic 0 and Logic 1 intervals. It increments when the re-synchronized pattern value equals 1 and decrements when it equals 0, or vice versa. Without edge jitter or metastability, the interval counter 70 resets to zero at the end of each Logic 0/Logic 1 cycle due to the 50% duty cycle (signal rst in FIG. 2). However, any non-zero value indicates unequal intervals caused by edge jitter or metastability. The absolute value of the interval counter 70 at the end of each cycle is added to the metastability count. The interval counter 70 is then reset for the next set of Logic 1/0 intervals.

Compared to a conventional XOR-based metastability detector, which detects metastability by comparing signals sampled at different clock edges, the interval-based metastability detector 60 according to example embodiments of the present disclosure provides a more nuanced detection by focusing on interval durations and leveraging the expected 50% duty cycle of the calibration pattern. This is also why the metastability detector according to example embodiments of the present disclosure is referred to as the interval-based detector 60.

The present disclosure thus detects and mitigates metastability of signals in distributed synchronous systems 10. By providing a metastability detector 60 integrating hardware such as an interval counter 70 and control logic 80 adapted to determine a metastability value based on deviations from the 50% duty cycle, and by providing a calibration method that adjusts clock phases based on metastability values determined by measuring deviations from the 50% duty cycle, example embodiments of the present disclosure may provide reliable, high-speed data transfer with minimal synchronization issues in distributed synchronous systems 10. The approach may further account for variations over time and because of operating conditions, thereby maintaining optimal performance of data transfer in distributed synchronous systems 10.

While some embodiments have been illustrated and described in detail in the appended drawings and the foregoing description, such illustration and description are to be considered illustrative and not restrictive. Other variations to the disclosed embodiments may be understood and effected in practicing the claims, from a study of the drawings, the disclosure, and the appended claims. The mere fact that certain measures or features are recited in mutually different dependent claims does not indicate that a combination of these measures or features cannot be used. Any reference signs in the claims should not be construed as limiting the scope.

What is claimed is:

1. A metastability detector for detecting metastability of a received signal in a distributed synchronous system, the metastability originating from clock phase misalignment resulting from sending the received signal from a first transceiver device to a second transceiver device of the distributed synchronous system, the metastability detector comprising:
an input configured to receive a re-synchronized signal pattern from a synchronizer device of the second transceiver device, wherein the re-synchronized signal pattern is obtained by re-synchronization to a signal pattern present in the received signal and resulting from a toggle sequence generated in the first transceiver device with a first clock phase and a 50% duty cycle;
an interval counter configured to increment when the re-synchronized signal pattern is equal to 1 and to decrement when the re-synchronized signal pattern is equal to 0 for a logic level interval of the re-synchronized signal pattern; and
a controller configured to accumulate an absolute value of the interval counter at an end of the logic level interval and to provide a metastability value based on the accumulated absolute value.

2. The metastability detector according to claim 1, wherein the interval counter is further configured to increment when the re-synchronized signal pattern is equal to 0 and to decrement when the re-synchronized signal pattern is equal to 1 for another logic level interval of the re-synchronized signal pattern.

3. The metastability detector according to claim 1, further comprising an internal register for storing the metastability value, wherein the internal register is externally accessible.

4. The metastability detector according to claim 1, wherein the controller is further configured to compare the accumulated absolute value of the interval counter to a predetermined threshold to determine if a metastability event has occurred.

5. A method for calibrating a distributed synchronous system comprising a first transceiver device with a first transceiver digital sub-system connected to a second transceiver device with a second transceiver digital sub-system via an external connection, the method comprising:
generating a toggle sequence with a clock phase and a 50% duty cycle in a pattern generator in the first transceiver digital sub-system, and transmitting a signal containing the toggle sequence to the second transceiver device;
receiving the signal in the second transceiver device, and synchronizing to a signal pattern in the received signal and resulting from the toggle sequence, with a synchronizer device in the second transceiver digital sub-system to provide a re-synchronized signal pattern;
incrementing an interval counter when the re-synchronized signal pattern is equal to 1 and decrementing the interval counter when the re-synchronized signal pattern is equal to 0 for a logic level interval of the re-synchronized signal pattern;
accumulating an absolute value of the interval counter at an end of the logic level interval and providing a metastability value based on the accumulated absolute value;
evaluating whether the metastability value is zero;
determining a reference clock phase correlated with the metastability value of zero; and
adjusting the clock phase of a signal for data transfer from the first transceiver device to the second transceiver device based on the reference clock phase.

6. The method according to claim 5, further comprising incrementing the interval counter when the re-synchronized signal pattern is equal to 0 and decrementing the interval counter when the re-synchronized signal pattern is equal to 1 for a subsequent logic level interval of the re-synchronized signal pattern.

7. The method according to claim 5, further comprising adjusting the clock phase of a signal for data transfer from the second transceiver device to the first transceiver device based on the reference clock phase.

8. The method according to claim 5, further comprising generating at least one further metastability value based on a further toggle sequence with a different clock phase and with a 50% duty cycle.

9. The method according to claim 5, further comprising comparing the metastability value with a predetermined metastability value.

10. The method according to claim 5, further comprising generating subsequent toggle sequences wherein the clock phase is adjusted over a range of clock phases.

11. The method according to claim 5, further comprising periodically calibrating the distributed synchronous system between data transfer operations.

12. A distributed synchronous system comprising:
a first transceiver device with a first transceiver digital sub-system; and
a second transceiver device connected to the first transceiver device, wherein:
the second transceiver device includes a second transceiver digital sub-system via an external connection;
the first transceiver digital sub-system includes a pattern generator for generating a toggle sequence with a clock phase and a 50% duty cycle; and
the first transceiver digital sub-system is configured to generate subsequent toggle sequences with different clock phases; and
the second transceiver digital sub-system includes:
a synchronizer device configured to receive a signal pattern present in a received signal and resulting from a toggle sequence generated in the first transceiver device, and to produce a re-synchronized signal pattern by re-synchronization to the received signal pattern; and
a metastability detector device to provide a metastability value of the re-synchronized signal pattern indicative of a degree of metastability of the re-synchronized signal pattern,
wherein the metastability detector device includes at least one metastability detector, or
wherein the distributed synchronous system is configured to perform, before or between transferring data, a calibration method for obtaining synchronized data transfer between the first transceiver device and the second transceiver device.

13. The system according to claim 12, wherein at least one metastability detector comprises:
an input configured to receive the re-synchronized signal pattern from the synchronizer device of the second transceiver device; and
an interval counter configured to increment when the re-synchronized signal pattern is equal to 1 and to decrement when the re-synchronized signal pattern is equal to 0 for a logic level interval of the re-synchronized signal pattern, or
increment when the re-synchronized signal pattern is equal to 0 and to decrement when the re-synchronized signal pattern is equal to 1 for a logic level interval of the re-synchronized signal pattern; and
a controller configured to accumulate an absolute value of the interval counter at an end of the logic level interval and to provide a metastability value based on the accumulated absolute value.

14. The system according to claim 12, wherein the calibration method comprises:
evaluating whether the metastability value reflects a metastability of zero;
determining a reference clock phase correlated with the metastability value reflecting the metastability of zero; and
adjusting the clock phase of a signal for data transfer from the first transceiver device to the second transceiver device based on the reference clock phase.

15. The system according to claim 12, wherein the metastability detector device further comprises at least one XOR based metastability detector or at least one pattern-based metastability detector, or wherein the synchronizer device comprises at least two Flip-Flop synchronizers.

16. The system according to claim 12, wherein the system is configured to periodically re-run the calibration method in between data transfer operations.

17. The system according to claim 12, wherein the first transceiver device comprises a field-programmable gate array with a phase-locked loop for clock phase adjustment, or wherein the second transceiver device comprises an integrated circuit configured to provide a reference clock phase to the first transceiver device.

18. The system according to claim 12, wherein the external connection comprises a transmitter core, transmitter pads, wires, receiver pads, and a receiver core.

19. A method for transferring reliable high-speed data in a distributed synchronous system comprising a first transceiver device with a first transceiver digital sub-system connected to a second transceiver device with a second transceiver digital sub-system via an external connection, the method comprising:
implementing, at the second transceiver digital sub-system, a metastability detector device configured to detect metastability events resulting from clock phase misalignment, the metastability detector device comprising at least one metastability detector;
providing, at the first transceiver device, a pattern generator for generating a toggle sequence with a first clock phase and a 50% duty cycle, and configured to generate subsequent toggle sequences with a plurality of second clock phases; or
performing, before use or in between data transfer operations, a calibration method;
selecting a clock phase from the first clock phase or the plurality of second clock phases resulting in a metastability of zero for data transfer; and
transferring data from the first transceiver device to the second transceiver device using the selected clock phase.

20. The method according to claim 19, further comprising the metastability detector of claim 1 and the calibration method of claim 5.
